(19) United States
(12) Patent Application Publication
(10) Pub. No.: US 2024/0134290 A1
(43) Pub. Date: Apr. 25, 2024

(54) MULTI-WAVELENGTH SELECTION METHOD FOR OVERLAY MEASUREMENT, AND OVERLAY MEASUREMENT METHOD AND SEMICONDUCTOR DEVICE MANUFACTURING METHOD USING MULTI-WAVELENGTHS

(71) Applicant: Samsung Electronics Co., Ltd., Suwon-si (KR)

(72) Inventors: Inbeom Yim, Suwon-si (KR); Junseong Yoon, Suwon-si (KR); Seungyoon Lee, Suwon-si (KR); Jeongjin Lee, Suwon-si (KR); Chan Hwang, Suwon-si (KR)

(21) Appl. No.: 18/332,238

(22) Filed: Jun. 9, 2023

(30) Foreign Application Priority Data
Oct. 17, 2022 (KR) 10-2022-0133606

(51) Int. Cl. G03F 7/20; G03F 7/00; H01L 21/66

(52) U.S. Cl. CPC G03F 7/70633; G03F 7/706831; G03F 7/706837; H01L 22/20

(57) ABSTRACT

Provided are a method of selecting multi-wavelengths for overlay measurement, for accurately measuring overlay, and an overlay measurement method and a semiconductor device manufacturing method using the multi-wavelengths. The method of selecting multi-wavelengths for overlay measurement includes measuring an overlay at multiple positions on a wafer at each of a plurality of wavelengths within a set first wavelength range, selecting representative wavelengths that simulate the overlay of the plurality of wavelengths, from among the plurality of wavelengths, and allocating weights to the representative wavelengths, respectively.

### CROSS-REFERENCE TO RELATED APPLICATIONS

This application is based on and claims priority under 35 U.S.C. § 119 to Korean Patent Application No. 10-2022-0133606, filed on Oct. 17, 2022, in the Korean Intellectual Property Office, the disclosure of which is incorporated by reference herein in its entirety.

### BACKGROUND

The inventive concept relates to an overlay measurement method, and more particularly, to a method of selecting multi-wavelengths to be used in overlay measurement, and an overlay measurement method and a semiconductor device manufacturing method using the multi-wavelengths.

In semiconductor devices or semiconductor wafers including the semiconductor devices, patterns of adjacent layers need to be accurately aligned. Accordingly, overlay measurement may be performed to align the patterns. In detail, an overlay may refer to a degree of mismatch between two layers when an exposure process is performed on a previous layer of a semiconductor substrate and then another exposure process is performed on a next layer or a current layer after several processes. Correcting relative positions between layers refers to overlay correction, and overlay measurement may be performed for such overlay correction. Overlay measurement refers to measuring a degree of mismatch among layers, that is, an overlay mismatch or an overlay error.

### SUMMARY

The inventive concept provides a method of selecting multi-wavelengths for overlay measurement, for accurately measuring an overlay, and an overlay measurement method and a semiconductor device manufacturing method using the multi-wavelengths.

In addition, the advantages and features of the inventive concept are not limited to the above-mentioned ones, and other advantages and features may be clearly understood by those skilled in the art from the description below.

According to an aspect of the inventive concept, there is provided a multi-wavelength selection method for overlay measurement, the method including measuring an overlay at multiple positions on a wafer at each of a plurality of wavelengths within a set first wavelength range, selecting representative wavelengths that simulate the overlay of the plurality of wavelengths from among the plurality of wavelengths, and allocating weights to the representative wavelengths, respectively.

According to another aspect of the inventive concept, there is provided an overlay measurement method including selecting a plurality of wavelengths for overlay measurement, setting up an overlay measurement recipe based on the plurality of wavelengths, and measuring an overlay by using the plurality of wavelengths based on the overlay measurement recipe, wherein the selecting of the plurality of wavelengths includes measuring an overlay at multiple positions on a wafer at each of the plurality of wavelengths within a set wavelength range, selecting representative wavelengths that simulate the overlay of the plurality of wavelengths from among the plurality of wavelengths, and allocating weights to the representative wavelengths, respectively.

According to another aspect of the inventive concept, there is provided a semiconductor device manufacturing method, the method including selecting a plurality of wavelengths for overlay measurement, setting up an overlay measurement recipe based on the plurality of wavelengths, measuring an overlay by using the plurality of wavelengths based on the overlay measurement recipe, correcting the overlay and forming a pattern based on the measured overlay, determining whether an overlay of the pattern is within a set reference range, and when the overlay of the pattern is within the reference range, performing a subsequent semiconductor process.

### BRIEF DESCRIPTION OF THE DRAWINGS

Embodiments will be more clearly understood from the following detailed description taken in conjunction with the accompanying drawings in which:

FIG. 1 is a schematic flowchart of a method of selecting multi-wavelengths for overlay measurement, according to an embodiment;

FIGS. 2A and 2B are respectively a conceptual diagram of an overlay mark for illustrating changes in an overlay according to wavelengths and according to a symmetrical or asymmetrical shape of the overlay mark, and a graph illustrating the overlay for each wavelength;

FIGS. 3A and 3B are graphs illustrating an overlay for each wavelength for illustrating an overlay measurement operation and an operation of selecting representative wavelengths, in the method of selecting multi-wavelengths for overlay measurement, of FIG. 1;

FIGS. 4A and 4B are photographic images of a mis-reading correction (MRC) distribution for illustrating an operation of allocating weights to representative wavelengths in the method of FIG. 1, of selecting multi-wavelengths for overlay measurement;

FIG. 5 is a flowchart for further illustrating the operation of selecting representative wavelengths in the method of selecting multi-wavelengths for overlay measurement of FIG. 1;

FIGS. 6A to 6C are graphs for illustrating an operation of extracting eigenvectors and selecting representative eigenvectors in the operation of FIG. 5 of selecting representative wavelengths;

FIGS. 7A and 7B are graphs for illustrating wavelength combinations according to thin plate spline (TPS) fitting score calculation in the operation of selecting representative wavelengths of FIG. 5;

FIG. 8 is a schematic flowchart of an overlay measurement method using multi-wavelengths according to an embodiment;

FIGS. 9A and 9B are respective graphs illustrating coefficients of model parameters of a wafer or field related to an overlay and graphs of a distribution of coefficients for each model parameter in the overlay measurement method of FIG. 8 and an overlay measurement method of a comparative example;

FIGS. 10A and 10B are respective graphs illustrating coefficients of model parameters of a wafer or field related to MRC and graphs of a distribution of coefficients for each model parameter in the overlay measurement method of FIG. 8 and the overlay measurement method of the comparative example; and

FIG. 11 is a schematic flowchart of a semiconductor device manufacturing method using multi-wavelengths according to an embodiment.

### DETAILED DESCRIPTION OF THE EMBODIMENTS

Hereinafter, embodiments of the inventive concept will be described more fully with reference to the accompanying drawings. In the drawings, like elements are labeled like reference numerals and repeated description thereof will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

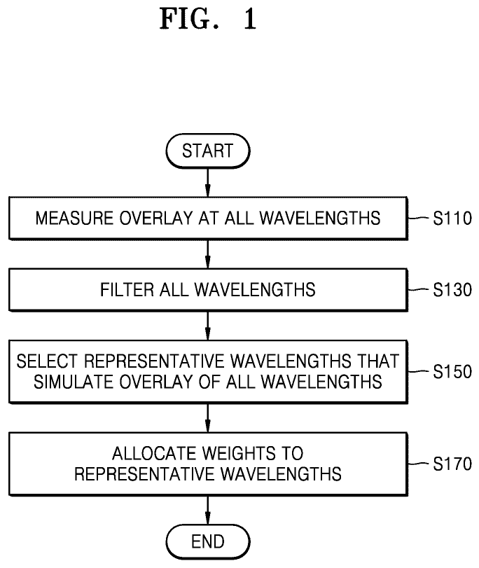

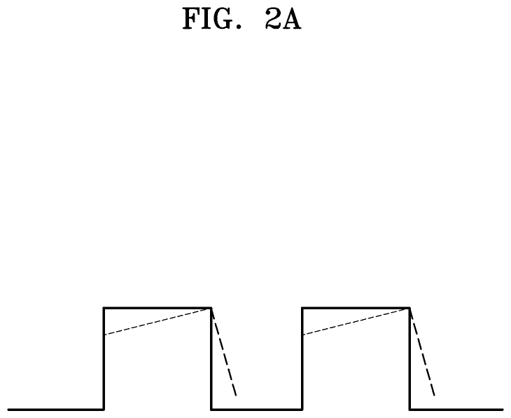

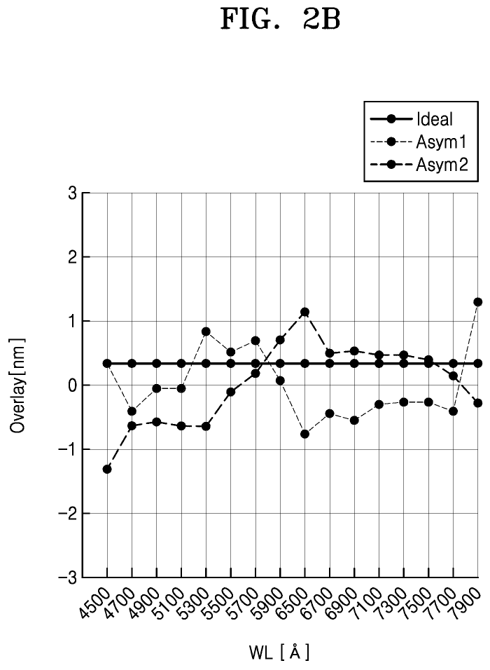

FIG. 1 is a schematic flowchart of a method of selecting multi-wavelengths for overlay measurement, according to an embodiment. FIGS. 2A and 2B are respectively a conceptual diagram of an overlay mark for illustrating changes in an overlay according to wavelengths and according to a symmetrical or asymmetrical shape of the overlay mark, and a graph illustrating the overlay for each wavelength. In the graph of FIG. 2B, the x-axis represents wavelengths and is in units of Å, and the y-axis represents an overlay and is in units of nm.

Referring to FIGS. 1 to 2B, in the method of selecting multi-wavelengths for overlay measurement of the present embodiment (hereinafter, simply referred to as ‘multi-wavelength selection method’), first, an overlay is measured at multiple positions on a wafer at each of a plurality of wavelengths in operation S110. Here, the overlay may have substantially the same meaning as an ‘overlay error’.

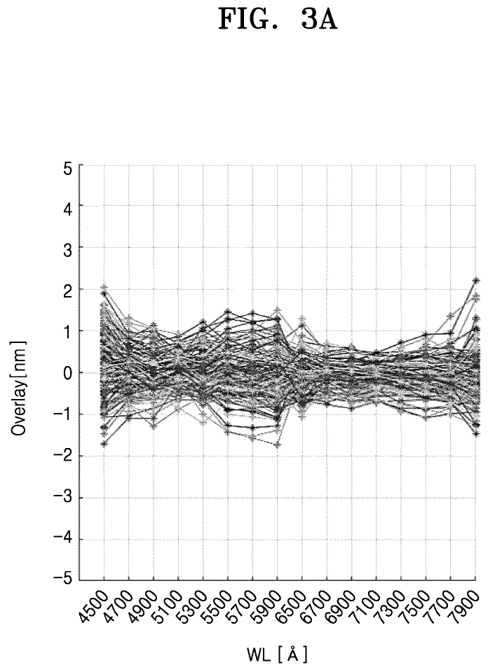

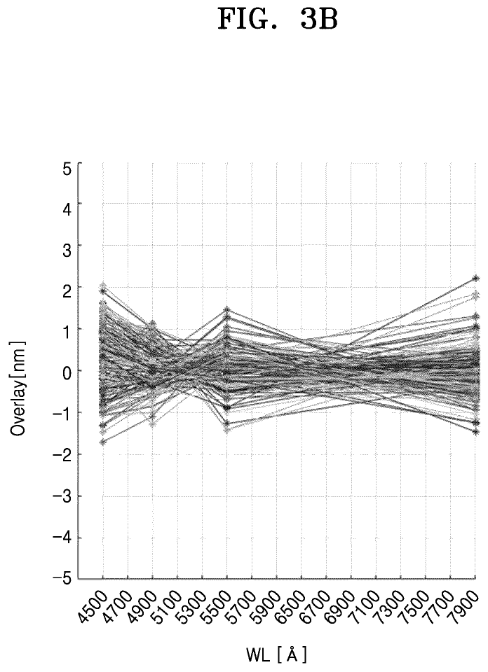

Each of the plurality of wavelengths may be included within visible light ranging, for example, from about 4100 nm to about 8200 nm. In addition, the wavelengths may be divided at intervals of 100 nm and a total number of the wavelengths may be 42. However, the wavelength range and the intervals between the wavelengths are not limited to the above numerical ranges and may vary in accordance with different embodiments. The number of multiple positions on a wafer may, however, be hundreds to thousands. For example, in the multi-wavelength selection method of the present embodiment, the number of multiple positions of a wafer, at which an overlay is to be measured, may be about 800. However, the number of multiple positions on the wafer is not limited to 800. By measuring the overlay by using each of the plurality of wavelengths, the graph of an overlay versus wavelength may be obtained as shown in FIG. 3A.

The reason for measuring an overlay by using each of the plurality of wavelengths is to predict an error in overlay measurement due to an asymmetry of an overlay mark, that is, misreading in the overlay measurement. In further detail, referring to FIGS. 2A and 2B, as generally indicated by the solid line in FIG. 2A, when the overlay mark is symmetrical, and an overlay is measured using this symmetric overlay mark, then, as shown by a solid line graph of FIG. 2B, for each of the plurality of wavelengths, substantially the same overlay may be measured. For example, in the graph of FIG. 2B, the overlay is shown as 0.3 nm.

However, as indicated by the thin dashed line in FIG. 2A, when the overlay is measured using a left-right asymmetric overlay mark in which the left side is shorter than the right side, then as shown in the overlay graph (Asym1) for the wavelength of the thin dashed line in FIG. 2B, the overlay may be measured differently according to different wavelengths. In addition, even when the overlay is measured using a left-right asymmetric overlay mark in which the left side is vertical and the right side is an oblique line, as indicated by the thick dashed line in FIG. 2B, as shown in the overlay graph for the wavelength of the thick dashed line of FIG. 2B (Asym2), the overlay may be measured differently according to different wavelengths.

For reference, the overlay marks of FIG. 2A may denote overlay marks of a lower layer. Because an overlay is usually measured after an exposure process, the overlay marks may be After Development Inspection (ADI) overlay marks. In addition, an overlay measured using an ADI overlay mark is also referred to as an ADI overlay.

As described above, the purpose of overlay measurement is to measure an overlay mark for alignment between a current layer and a previous lower layer, and thus to determine an overlay level, that is, a misalignment level, and correct the same. In general, in overlay measurement, a single wavelength may be used. When measuring an overlay using a single wavelength, there is generally no problem if the overlay mark is symmetrical, However, if the overlay mark is asymmetrical, the overlay varies according to wavelengths used, and the measured overlay may not correspond to an accurate overlay.

In general, a pattern may be formed on a previous lower layer, and then, after several processes, the pattern may be formed on a current layer. In addition, an overlay mark of a lower layer, for example, a main pattern (or outer mark), may be formed together when forming a pattern of the lower layer, and an overlay mark of a current layer, for example, a vernier patter (or, inner mark), may be formed together when forming a pattern of the current layer. However, as a number of processes are performed before forming the pattern of the current layer, the overlay mark of the lower layer may be damaged. Accordingly, even when the overlay mark of the lower layer is initially formed in a symmetrical shape, the overlay mark of the lower layer may be an asymmetrical shape during overlay measurement after forming the overlay of the current layer. As a result, when an overlay is measured using a single wavelength, an accurate overlay may not be measured, and thus overlay correction cannot be accurately performed.

As shown in FIGS. 2A and 2B, an overlay mark of a certain shape may correspond to an overlay graph for a wavelength of a certain shape. In other words, the overlay mark of the thin dashed line in FIG. 2A may correspond to the overlay graph (Asym1) for the wavelengths of the thin dashed line in FIG. 2B, and the overlay mark of the thick dashed line in FIG. 2A may correspond to the overlay graph (Asym2) for the wavelengths of the thick dashed line in FIG. 2B. Therefore, by measuring an overlay by using multi-wavelengths at multiple positions and identifying a trend in the overlay graph with respect to the wavelengths, the asymmetric shape of the overlay mark may be predicted. In addition, components of mis-measurement of the overlay due to the asymmetry of the overlay mark, that is, mis-reading components, may be predicted, and accordingly, accurate overlays may be calculated by reflecting the mis-reading components.

When an overlay is measured using each of a plurality of wavelengths, it takes a relatively long measurement time, thereby significantly increasing turn around time (TAT). Accordingly, a process of selecting appropriate wavelengths from among all of the wavelengths that are representative of all of the wavelengths may be desired. The selected wavelengths may well simulate an overlay tendency of all the wavelengths to accurately predict mis-reading components due to the asymmetry of the overlay mark. In addition, a minimum number of wavelengths may be selected to maintain a low TAT.

After measuring the overlay, all the wavelengths are filtered in operation S130. Here, filtering may refer to a process of removing those wavelengths that represent an overlay that deviates greatly from an actual overlay. For example, the actual overlay should be included within a range of about −2 nm to about 2 nm, but if the overlay is measured below −2 nm or greater than 2 nm at a certain wavelength, filtering may refer to a process of excluding the corresponding wavelength. This filtering process may be performed to promptly and accurately select wavelengths later by removing unnecessary wavelengths in advance, rather than selecting appropriate wavelengths.

In the multi-wavelength selection method of the present embodiment, filtering may be automatically performed using a Key Parameter Index (KPI) reflecting characteristics of an overlay mark. The KPI is a criterion for selecting a wavelength and may be set differently according to overlay marks and/or measurement equipment.

After filtering with respect to each of the plurality of wavelengths, representative wavelengths simulating an overlay by all of the plurality of wavelengths are selected in operation S150. The representative wavelengths may correspond to appropriate wavelengths described above. The representative wavelengths may be selected based on Principal Component Analysis (PCA). In addition, the representative wavelengths may be selected based on singular value decomposition (SVD). PCA or SVD is a dimensionality reduction technique. In the multi-wavelength selection method of the present embodiment, PCA or SVD may be used to extract, for example, 42 overlay graphs for wavelengths from among 800 overlay graphs for wavelengths. Here, 800 may correspond to the number of multiple positions on a wafer, and 42 may correspond to the total number of wavelengths.

In addition, in the multi-wavelength selection method of the present embodiment, the representative wavelengths may be selected using weights of overlay graphs for previously extracted wavelengths, Radial Basis Function (RBF) fitting scores, or Thin Plate Spline (TPS) fitting scores. In the multi-wavelength selection method of the present embodiment, ten or less representative wavelengths may be selected. However, the number of selected representative wavelengths is not limited to ten or less.

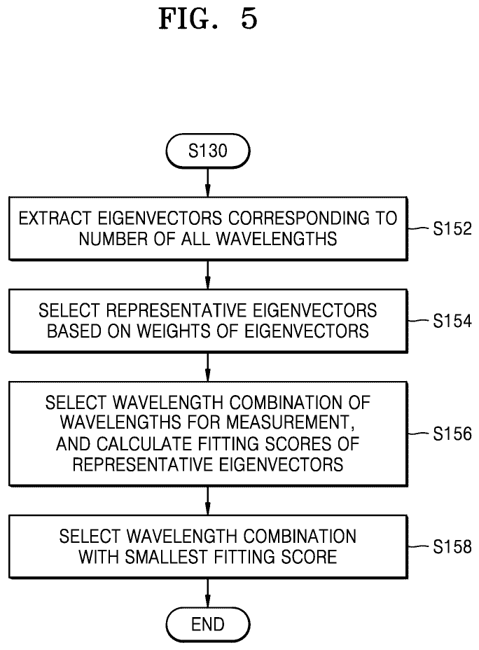

A method of extracting 42 overlay graphs for wavelengths by using SVD and selection of representative wavelengths by using weights and RBF fitting scores or TPS fitting scores, according to some embodiments, is described in detail in the description with respect to FIGS. 5 to 7B.

After selecting the representative wavelengths, weights are allocated to the representative wavelengths in operation S170. Weight allocation for the representative wavelengths may be performed using a combination of weights having a smallest mis-reading correction (MRC) distribution among combinations in which a sum of the weights equals 1. For example, when there are four representative wavelengths and weights are allocated in units of 0.1, when an MRC distribution is 3.5 in a first combination in which 0.2 is allocated to a first wavelength WL1, 0.3 to a second wavelength WL2, 0.4 to a third wavelength WL3, and 0.1 to a fourth wavelength WL4, and when an MRC distribution is 2.8 in a second combination in which 0.1 is allocated to the first wavelength WL1, 0.4 to the second wavelength WL2, 0.3 to the third wavelength WL3, and 0.2 to the fourth wavelength WL4, the weights of the second combination may be allocated to the representative wavelengths. Here, the MRC distribution may be expressed as a 3 sigma (σ) value. However, the MRC distribution is not necessarily limited to the 3 sigma value.

Here, MRC may refer to a difference between an overlay of an overlay mark and an on-cell overlay. Also, on-cell overlay may refer to an overlay between actual patterns. For reference, the purpose of overlay measurement is to correct an overlay of patterns. Therefore, it is desirable to correct an overlay by measuring an overlay of actual patterns. However, since the shapes of the patterns are generally diverse and fine, it may take a lot of time to measure the overlay of the actual patterns. Accordingly, instead of measuring the overlay of the actual patterns, the overlay may be measured using an overlay mark of a preset shape, and the overlay of the patterns may be corrected based on the measured overlay.

When the overlay of the overlay mark exactly matches the overlay of the patterns, the overlay of the patterns may be made 0 by correcting the overlay obtained from overlay mark measurement. However, if the overlay of the overlay mark and the overlay of the patterns do not exactly match each other, the overlay of the patterns may not be accurately corrected even if the overlay obtained by measuring the overlay mark is corrected. Thus, the overlay of the patterns may still be present.

The MRC distribution may refer to a distribution of differences between an overlay of an overlay mark and an on-cell overlay at various positions of a wafer. In other words, after overlay correction, the MRC distribution may refer to a distribution of on-cell overlays at various positions of the wafer. In addition, due to the asymmetry of the overlay mark, if the overlay obtained from the overlay mark measurement is inaccurate, MRC may increase and the MRC distribution may also increase, accordingly. However, when measuring an overlay mark based on the multi-wavelength selection method of the present embodiment, despite the asymmetry of the overlay mark, an accurate overlay may be obtained. Accordingly, MRC may decrease, and an MRC distribution according to the same may also decrease.

Regarding the process of allocating weights to the representative wavelengths, allocating weights that minimize an MRC distribution to the representative wavelengths means that, after all, measuring an overlay with the representative wavelengths and weights allocated thereto enables an ability to measure an accurate overlay. That is, the process of allocating weights to the representative wavelengths may correspond to a process of excluding mis-reading components resulting from asymmetry of the overlay mark.

The multi-wavelength selection method of the present embodiment may include measuring an overlay at each of the plurality of wavelengths, filtering the plurality of wavelengths, selecting representative wavelengths that simulate the overlay of the plurality of wavelengths, and allocating weights to the representative wavelengths. In addition, according to the multi-wavelength selection method of the present embodiment, the representative wavelengths obtained through the above process and the weights allocated thereto may be applied to an overlay measurement recipe, and an overlay may be measured, thereby excluding mis-reading due to asymmetry of an overlay mark and accurately measuring the overlay. Therefore, according to the multi-wavelength selection method of the present embodiment, the accuracy of overlay measurement may be improved, and an on-cell overlay, that is, the level of on-cell misalignment, may be reduced. Furthermore, by enabling overlay measurement by using ten or less representative wavelengths, the overlay measurement time and TAT according to the same may be reduced or minimized.

FIGS. 3A and 3B are graphs of an overlay for wavelengths, for illustrating an overlay measurement operation and an operation of selecting representative wavelengths in the multi-wavelength selection method of FIG. 1. In the graphs of FIGS. 3A and 3B, the x-axis represents wavelengths and is in units of Å, and the y-axis represents an overlay and is in units of nm. Descriptions of features provided already with reference to FIGS. 1 to 2B are briefly provided or omitted.

Referring to FIG. 3A, in the overlay measurement operation (S110) of the multi-wavelength selection method of the present embodiment, an overlay graph for wavelengths may be obtained by measuring an overlay at multiple positions on a wafer, at all of the plurality of wavelengths. The plurality of wavelengths are included within a range of about 4500 nm to about 7900 nm, and may be divided at intervals of 200 nm. In FIG. 3A, wavelengths of 6100 nm and 6200 nm are excluded through filtering and the rest of wavelengths are displayed, and thus, the total wavelengths after the filtering may be 16. However, the range and intervals of the plurality of wavelengths are not limited to the above numerical ranges. On the other hand, the number of positions on a wafer where an overlay is measured may be, for example, 800. However, the number of positions on a wafer where an overlay is measured is not limited to 800.

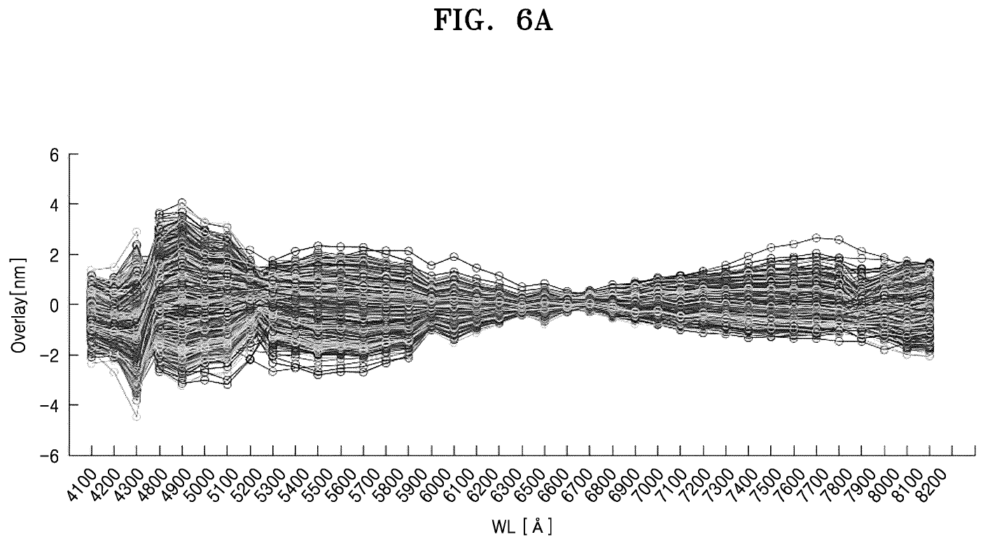

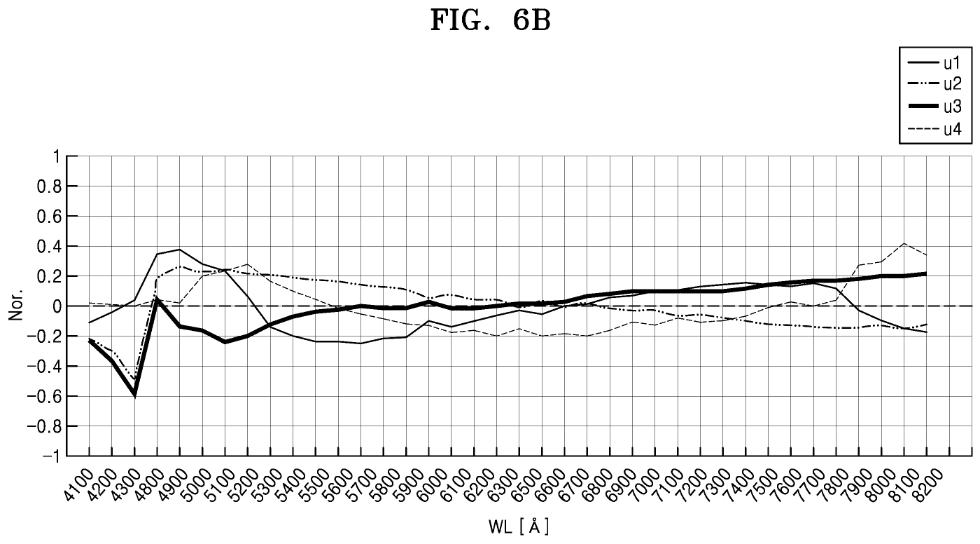

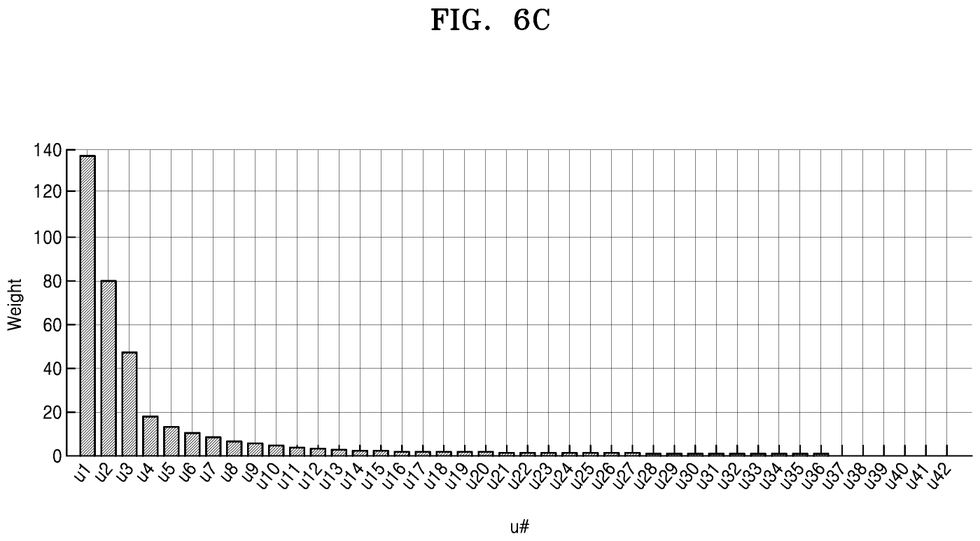

Referring to FIG. 3B, in the representative wavelength selection operation (S150) of the multi-wavelength selection method of the present embodiment, four representative wavelengths, for example, wavelengths of 4500 nm, 4900 nm, 5500 nm, and 7900 nm are selected through SVD. FIG. 3B shows an overlay graph for the four representative wavelengths. In other words, an overlay graph for the representative wavelengths may be obtained by removing overlays of wavelengths other than the representative wavelengths and connecting only the overlays of representative wavelengths. A process of selecting representative wavelengths by using SVD is described in detail in the description of FIGS. 5 to 6C.

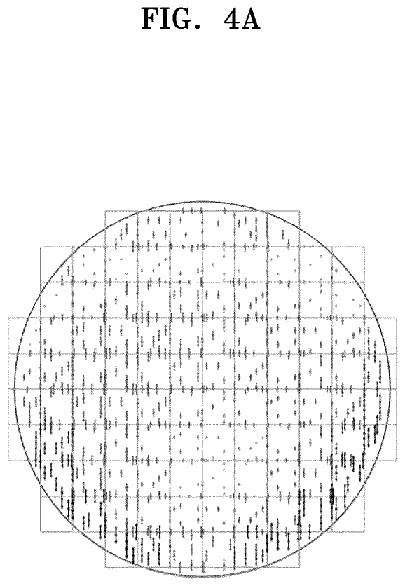

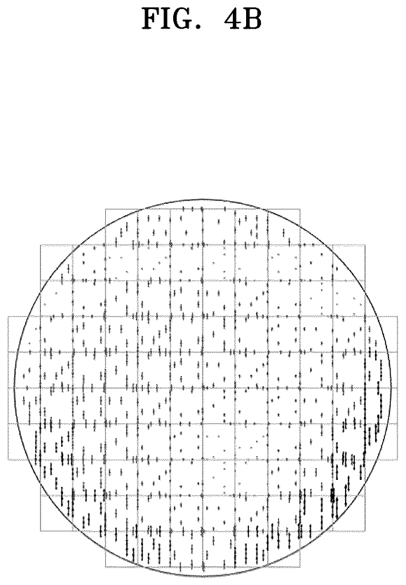

FIGS. 4A and 4B are photographic images of an MRC distribution for illustrating an operation of allocating weights to representative wavelengths in the multi-wavelength selection method of FIG. 1. FIG. 4A is a photographic image of an MRC distribution by overlay measurement using a single wavelength in the Comparative Example, and FIG. 4B is a photographic image of an MRC distribution according to overlay measurement using multi-wavelengths according to the present embodiment. Descriptions of features provided already with reference to FIGS. 1 to 3B are briefly provided or omitted.

Referring to FIGS. 4A and 4B, in the operation of selecting representative wavelengths of the multi-wavelength selection method of the present embodiment (S150), weight allocation for the representative wavelengths may be performed using a combination of weights having a smallest MRC distribution among combinations in which a sum of the weights equals 1. For example, as illustrated in FIG. 3B, when there are four representative wavelengths and weights are allocated in units of 0.1, when an MRC distribution is 3.4 in a first combination in which 0.3 is allocated to a first wavelength (4500 nm), 0.2 to a second wavelength (4900 nm), 0.4 to a third wavelength (5500 nm), and 0.1 to a fourth wavelength (7900 nm), and when an MRC distribution is 2.2 in a second combination in which 0.2 is allocated to the first wavelength (4500 nm), 0.3 to the second wavelength (4900 nm), 0.3 to the third wavelength (5500 nm), and 0.2 to the fourth wavelength (7900 nm), the weights of the second combination may be allocated to the representative wavelengths.

An MRC distribution by overlay measurement using a single wavelength of the comparative example of FIG. 4A is about 3.53. On the other hand, an MRC distribution according to the overlay measurement using multi-wavelengths of the present embodiment of FIG. 4B may be about 2.85. Here, multi-wavelengths may refer to, for example, the representative wavelengths that are previously selected. For reference, the MRC distributions of FIGS. 4A and 4B represent MRC distributions in the y-direction. Those expressed as dots may indicate a relatively small MRC, and those expressed as lines may indicate a relatively large MRC. In addition, squares in FIGS. 4A and 4B may correspond to fields dividing a wafer into several regions, and MRC characteristics may vary depending on the fields. For example, the MRC may be relatively large in lower outer fields of FIGS. 4A and 4B.

As a result, an accurate overlay may be obtained through the overlay measurement using multi-wavelengths of the present embodiment. Furthermore, the MRC distribution may be reduced by correcting the overlay based on accurate overlay measurement. Accordingly, the level of an on-cell overlay, that is, the on-cell misalignment level, may be improved.

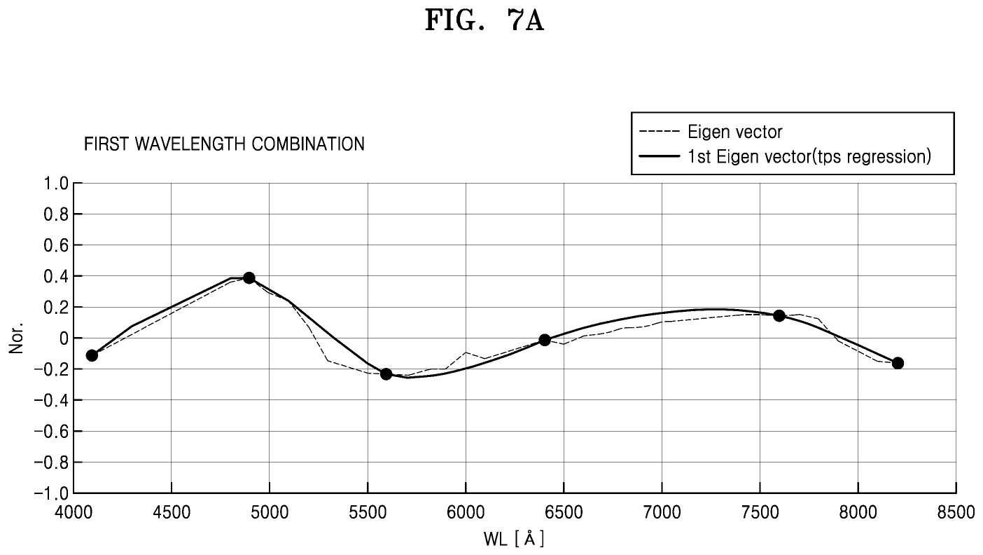

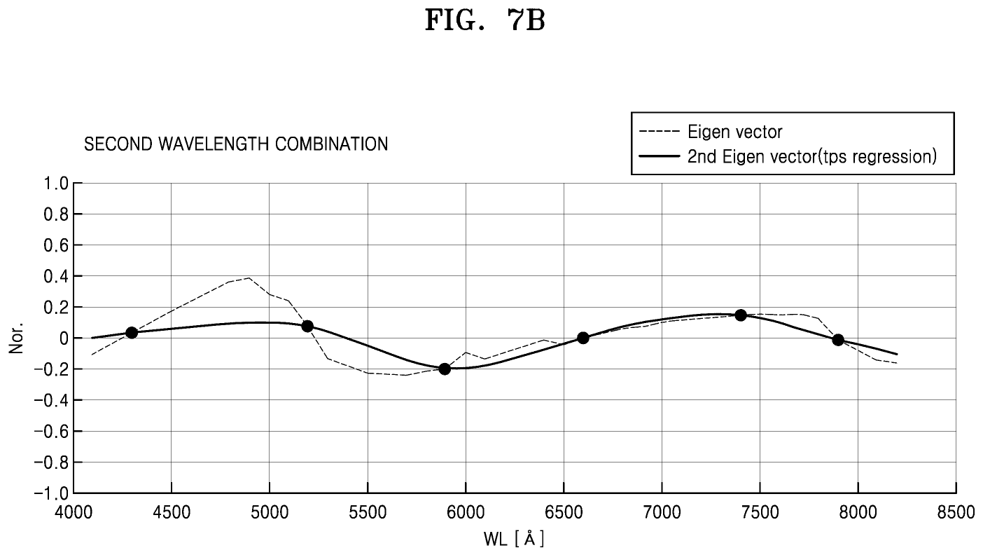

FIG. 5 is a flowchart for further describing the operation of selecting representative wavelengths in the multi-wavelength selection method for overlay measurement, of FIG. 1. FIGS. 6A to 6C are graphs that illustrate the process of extracting eigenvectors and selecting representative eigenvectors in the operation of selecting representative wavelengths of FIG. 5, and FIGS. 7A and 7B are graphs that illustrate wavelength combinations according to a TPS fitting score calculation in the operation of selecting representative wavelengths of FIG. 5. In FIG. 6B, the y-axis represents a normalized overlay, and in FIG. 6C, the x-axis represents types of eigenvectors, and the y-axis represents the weight. Also, in the graphs of FIGS. 7A and 7B, the x-axis represents wavelengths, and the y-axis represents a normalized overlay. Descriptions of features provided already with reference to FIGS. 1 to 4B are briefly provided or omitted.

Referring to FIGS. 5, 6A, and 6B, in the multi-wavelength selection method of the present embodiment, after performing the operations of measuring the overlay (S110) and filtering (S130), eigenvectors corresponding to the total number of all the wavelengths are extracted using SVD in operation S152. FIG. 6A shows a graph of positional overlay for all the wavelengths, and may correspond to a graph in which filtering is not reflected.

FIG. 6B shows four eigenvectors having a relatively high weight among the eigenvectors. Using SVD, eigenvectors may generally be extracted as many as the total number of all the plurality of wavelengths. In terms of a formula using a matrix, it is assumed that the graph of FIG. 6A represents an overlay of n wavelengths at m wafer positions. When the graph of FIG. 6A is expressed as a two-dimensional matrix M, the matrix M may have m rows and n columns. That is, the matrix M is an m*n matrix.

The matrix M may be expressed as a product of three matrices by SVD as shown in Equation (1) below.

M=U*Σ*V^{T} Equation (1)

In Equation (1), U and V are orthogonal matrices, are respectively square matrices of m*m and n*n, and V^{T} is a transposed matrix of V. A Σ matrix is a matrix having eigenvalues and is an m*n matrix.

Based on Equation (1), n eigenvectors corresponding to the V matrix may be obtained. Also, n eigenvectors may have weights according to the eigenvalues of the Σ matrix. In the graph of FIC. 6C, the weights for the eigenvectors are shown. A weight of an eigenvector may correspond to a criterion showing how similarly the corresponding eigenvector simulates an overlay graph of all the plurality of wavelengths. In other words, the larger the weight of the eigenvector, the more similarly the eigenvector may simulate the overlay graph of all the plurality of wavelengths.

After extraction of the eigenvectors, representative eigenvectors are selected based on the weight of the eigenvectors in operation S154. As described above, there are weights corresponding to eigenvectors, and the greater the weights, the more similarly the eigenvectors may simulate an overlay graph of all the wavelengths. Therefore, among the eigenvectors, representative eigenvectors may be selected in the order of increasing weights, and used for selecting the representative wavelengths later. In the multi-wavelength selection method of the present embodiment, ten or less representative eigenvectors may be selected. For example, as illustrated in FIG. 6B, four representative eigenvectors may be selected. However, the number of selected representative eigenvectors is not limited to ten or less in accordance with various embodiments.

After selecting the representative eigenvectors, a wavelength combination of wavelengths for measurement is selected and fitting scores are calculated for the representative eigenvectors in operation S156. The number of wavelengths for measurement may be substantially the same as the number of representative wavelengths. Also, the number of wavelengths for measurement may be substantially equal to the number of representative eigenvectors. Accordingly, the wavelengths for measurement may be set to ten or less. However, the number of wavelengths for measurement is not limited to ten or less in accordance with various embodiments.

After calculating the fitting scores, a wavelength combination having a smallest fitting score is selected in operation S158. Wavelengths included in the selected wavelength combination may correspond to the representative wavelengths.

Referring to FIGS. 7A and 7B, a process of calculating a fitting score and a process of selecting a wavelength combination according to an embodiment are described in detail. Meanwhile, in FIGS. 7A and 7B, each dashed line represents an eigenvector and may correspond to a first eigenvector u1 of FIG. 6B. In addition, in FIGS. 7A and 7B, solid lines may respectively correspond to a first approximate eigenvector and a second approximate eigenvector that are approximated by thin plate spline (tps) regression by a first wavelength combination and a second wavelength combination.

First, in the case of the first wavelength combination of FIG. 7A, for example, a wavelength combination of six wavelengths, 4100 nm, 4900 nm, 5600 nm, 6400 nm, 7600 nm, and 8200 nm, may be selected. Then, through tps regression, a first approximate eigenvector may be obtained. As shown in FIG. 7A, the first approximate eigenvector is significantly similar to the first eigenvector u1. Thus, a TPS fitting score thereof is also relatively low at 0.328. For reference, in general, the fitting score may increase as a difference between values at actual points and values on a graph approximated through regression or the like increases, and the fitting score may decrease as the difference decreases. That is, the smaller the fitting score, the better a graph obtained through approximation may represent actual data.

Meanwhile, in the case of the second wavelength combination of FIG. 7B, for example, a wavelength combination of six wavelengths, 4300 nm, 5200 nm, 5900 nm, 6600 nm, 7400 nm, and 7900 nm, may be selected. Then, in tps regression, the second approximate eigenvector may be obtained through tps regression. As show in FIG. 7B, the second approximate eigenvector is different from the first eigenvector u1, and in particular, the difference is large at relatively short wavelengths. In addition, it can be seen that a TPS fitting score thereof is also relatively high at 0.625.

Accordingly, if there are only two wavelength combinations, the first wavelength combination having a relatively small TPS fitting score may be selected. The wavelengths in the first wavelength combination, for example, 4100 nm, 4900 nm, 5600 nm, 6400 nm, 7600 nm, and 8200 nm, may correspond to the representative wavelengths.

In FIGS. 7A and 7B, the TPS fitting score is calculated for the first eigenvector u1. However, in practice, TPS fitting scores are calculated and summed with respect to representative eigenvectors, for example, all six representative eigenvectors corresponding to six wavelengths, and a wavelength combination having a minimum sum value may be selected. Also, although TPS fitting scores are calculated for two wavelength combinations, TPS fitting scores may be calculated for combinations of a number of wavelengths for measurement with respect to all the wavelengths. In other words, if the total number of all the wavelengths is T (T is an integer greater than 1) and the number of wavelengths for measurement is n (n is an integer greater than 1 and less than T), TPS fitting scores for each combination among combinations _{T}Cn for selecting n from T may be calculated.

The representative wavelengths may also be selected by selecting a wavelength combination by using an RBF fitting score F instead of a TPS fitting score. In the combinations _{T}Cn in which n, the number of wavelengths for measurement, is selected from T, the total number of wavelengths, the RBF fitting score F for each combination may be obtained through the following equation (2).

$$F = {\sum }_{k = 1}^{n} {F}_{k} {W}_{k} \qquad Equation ( 2 )$$

In Equation (2), Fₖ is an RBF fitting score of each of the wavelengths for measurement, and Wₖ may correspond to a weight allocated to an eigenvector corresponding to each of the wavelengths for measurement. Here, an eigenvector corresponding to each of the measurement wavelengths may refer to a representative eigenvector.

Similar to the above TPS fitting score, a wavelength combination having a smallest RBF fitting score F calculated through Equation (2) may be selected. Also, wavelengths included in the selected wavelength combination may correspond to the representative wavelengths. In detail, for example, when four wavelengths are selected, and the RBF fitting score F for a first wavelength combination of 4100 nm, 4500 nm, 6500 nm, and 6800 nm is 0.52, and the RBF fitting score F for a second wavelength combination of 4300 nm, 5500 nm, 6300 nm, and 7200 nm is 0.37, the second wavelength combination having a lower RBF fitting score F may be selected. Also, the wavelengths included in the second wavelength combination, for example, 4300 nm, 5500 nm, 6300 nm, and 7200 nm, may be the representative wavelengths.

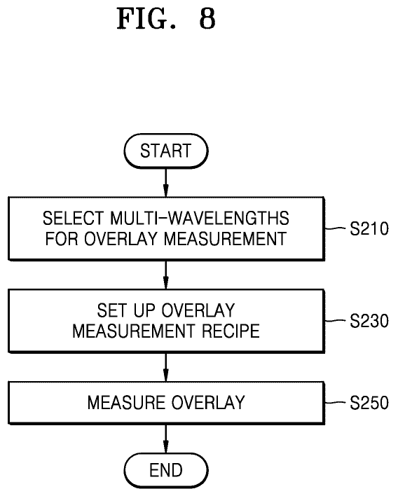

FIG. 8 is a schematic flowchart of an overlay measurement method using multi-wavelengths, according to an embodiment. Description is provided by referring to FIGS. 1 and 5 together, and details that are already described with respect to FIGS. 1 to 7B are briefly described or omitted.

Referring to FIG. 8, in the overlay measurement method using multi-wavelengths, according to the present embodiment (hereinafter, simply referred to as ‘overlay measurement method’), first, multi-wavelengths for overlay measurement are selected in operation S210. The operation of selecting multi-wavelengths (S210) may be substantially the same as the multi-wavelength selection method of FIG. 1. Therefore, the operation of selecting multi-wavelengths (S210) may include the operation of measuring an overlay (S110), the operation of filtering all the wavelengths (S130), the operation of selecting representative wavelengths (S150), and the operation of allocating weights to the representative wavelengths (S170). The operation of measuring an overlay (S110) to the operation of allocating weights to the representative wavelengths (S170) may be the same as described in the description of FIG. 1.

After selecting multi-wavelengths, an overlay measurement recipe is set up in operation S230. The overlay measurement recipe may refer to various measurement-related data and parameters used when measuring an overlay. For example, the overlay measurement recipe may include wavelengths used for measurement, weights of the wavelengths, locations to be measured, measurement time, and the like. For example, in the overlay measurement method of the present embodiment, setting up an overlay measurement recipe may mainly refer to reflecting previously selected representative wavelengths and weights allocated to the representative wavelengths so that they may be used in overlay measurement. Setting up of an overlay measurement recipe as above may refer to setting up of overlay measurement equipment that performs overlay measurement.

After setting up the overlay measurement recipe, an overlay is measured based on the newly set-up overlay measurement recipe, in operation S250. In other words, the overlay may be measured based on the selected representative wavelengths and the weights allocated to the representative wavelengths. Here, overlay measurement may refer to overlay measurement for an overlay mark.

The overlay measurement method of the present embodiment includes the selecting multi-wavelengths for overlay measurement (S210) and the setting up an overlay measurement recipe (S230), and thus, according to the method, an overlay may be accurately measured. That is, according to the overlay measurement method of the present embodiment, by selecting representative wavelengths that similarly simulate the overlay of all the plurality of wavelengths and measuring an overlay by using the representative wavelengths and the weight of the representative wavelengths, mis-reading components resulting from the asymmetry of an overlay mark may be excluded, and the overlay, that is, misalignment, may be accurately measured. Therefore, according to the overlay measurement method of the present embodiment, overlay measurement accuracy may be improved, and also, the level of on-cell overlay may be remarkably improved by precisely performing overlay correction based on the measurement accuracy.

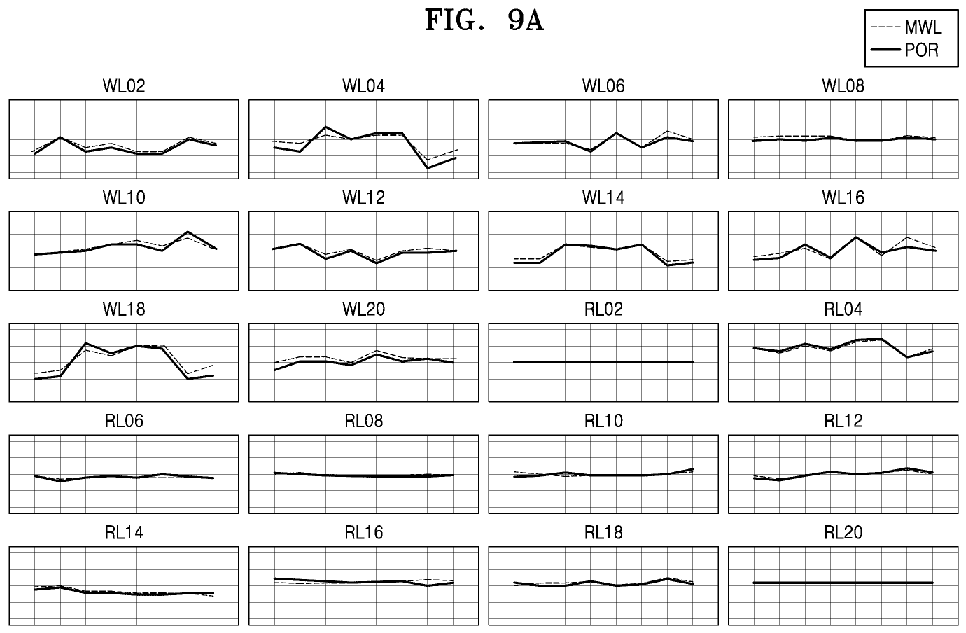

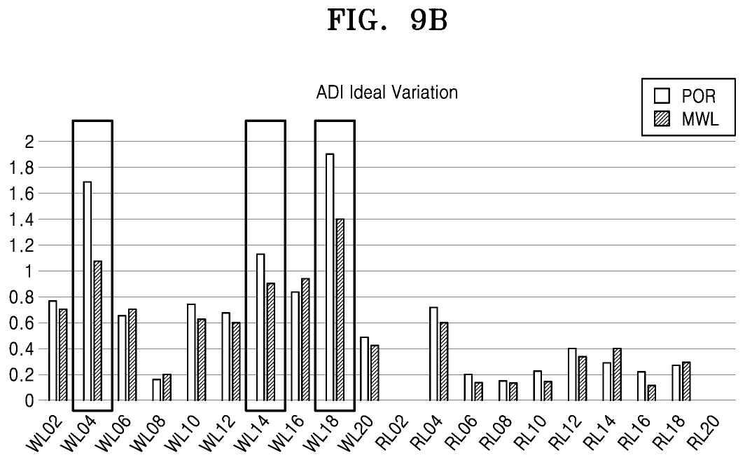

FIGS. 9A and 9B are respective graphs illustrating coefficients of model parameters of a wafer or field related to an overlay and graphs of a distribution of coefficients for each model parameter in the overlay measurement method of FIG. 8 and an overlay measurement method of a comparative example.

Referring to FIG. 9A, in FIG. 9A, WL graphs are graphs for model parameters of a wafer, the x-axis represents types of wafers, and the y-axis represents coefficients of model parameters. RL graphs are graphs of the model parameters of the field, the x axis represents the types of fields, and the y axis is the coefficient of the model parameter. Furthermore, in the WL graphs and the RL graphs, the solid line represents the overlay measurement method of the comparative example, and the dashed line represents the overlay measurement method according to the present embodiment.

As can be seen from FIG. 9A, there is no significant difference in the model parameters of the field, but in the case of the model parameters of the wafer, there is a difference among wafers. For reference, in general, coefficients of model parameters appear as 0 when no overlay exists, and coefficients of model parameters appear when an overlay exists. In addition, a difference between the coefficients of the model parameters in the overlay measurement of the present embodiment from the coefficients of the model parameters in the overlay measurement of the comparative example may indicate that the overlay according to overlay measurement according to the present embodiment is different from the overlay according to the overlay measurement of the comparative example.

FIG. 9B shows the distributions of the coefficients for model parameters. That is, in FIG. 9B, the x-axis represents model parameters, and the y-axis represents the distributions of the coefficients of the model parameters. As can be seen from FIG. 9B, the distributions of the coefficients in the model parameters of WL04, WL14, and WL18 are greatly improved. In other words, it can be stated that the distribution of the coefficients of the model parameters of the present embodiment is greatly reduced compared to the distribution of the coefficients of the model parameters of the comparative example.

On the other hand, a 3 sigma value of the distribution of the overlay of the comparative example is about 5.45/2.94, and that of distribution of the overlay according to the present embodiment is about 5.78/2.47. For reference, the front part of ‘/’ is for the x-axis direction and the rear part is for the y-axis direction, and the overlay distribution in the y-axis direction is subject to measurement. Therefore, when it is assumed that the overlay distribution in the x-axis direction is not considered, it may be confirmed that the overlay distribution by overlay measurement of the present embodiment is improved compared to the overlay distribution by overlay measurement of the comparative example.

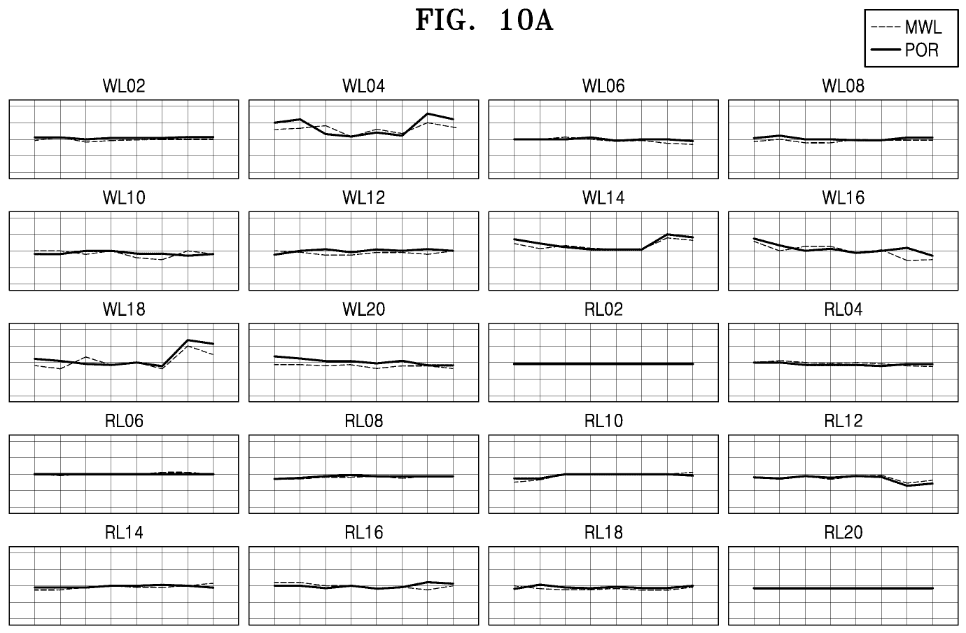

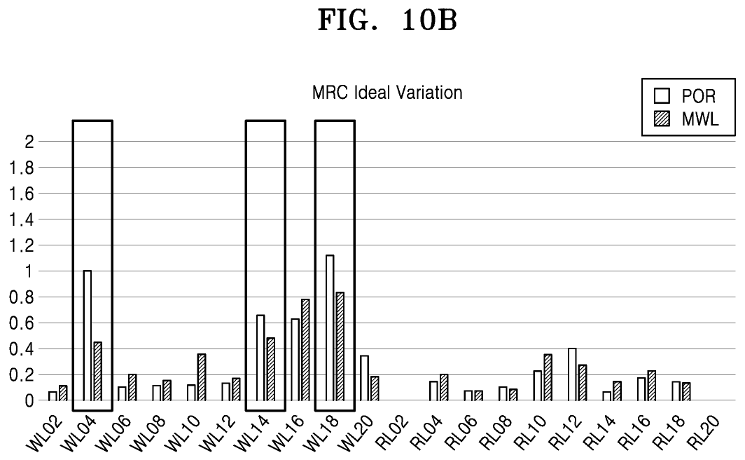

FIGS. 10A and 10B are respective graphs illustrating coefficients of model parameters of a wafer or field related to MRC and graphs of a distribution of coefficients for each model parameter in the overlay measurement method of FIG. 8 and the overlay measurement method of the comparative example.

Referring to FIG. 10A, in FIG. 10A, WL graphs are graphs for model parameters of a wafer, the x-axis represents types of wafers, and the y-axis represents coefficients of model parameters. RL graphs are graphs of the model parameters of the field, the x axis represents the types of fields, and the y axis is the coefficient of the model parameter. Furthermore, in the WL graphs and the RL graphs, the solid line represents the overlay measurement method of the comparative example, and the dashed line represents the overlay measurement method according to the present embodiment.

As can be seen from FIG. 10A, there is no significant difference in the model parameters of the field, but in the case of the model parameters of the wafer, there is a difference among wafers. For reference, in general, coefficients of model parameters appear as 0 when no MRC exists, and coefficients of model parameters appear when MRC exists. In addition, a difference between the coefficients of the model parameters in the overlay measurement of the present embodiment from the coefficients of the model parameters in the overlay measurement of the comparative example may indicate that the MRC according to overlay measurement according to the present embodiment is different from the MRC according to the overlay measurement of the comparative example.

FIG. 10B shows the distributions of coefficients for model parameters. That is, in FIG. 10B, the x-axis represents model parameters, and the y-axis represents the distributions of the coefficients of the model parameters. As can be seen from FIG. 10B, the distributions of the coefficients in the model parameters of WL04, WL14, and WL18 are greatly improved. In other words, it can be stated that the distribution of the coefficients of the model parameters of the present embodiment is greatly reduced compared to the distribution of the coefficients of the model parameters of the comparative example.

On the other hand, a 3 sigma value of the distribution of the MRC of the comparative example is about 0.00/1.38, and that of distribution of the MRC according to the present embodiment is about 0.00/1.13, and also, the distribution of MRC in the y-axis direction is subject to measurement. It is confirmed that the MRC distribution according to overlay measurement of the present embodiment is improved compared to the MRC distribution of overlay measurement according to the comparative example.

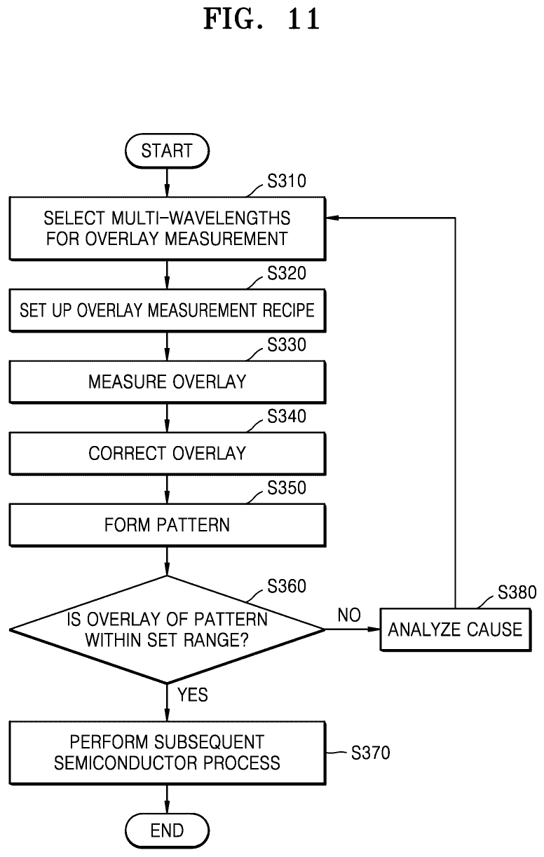

FIG. 11 is a schematic flowchart of a semiconductor device manufacturing method using multi-wavelengths, according to an embodiment. Description is provided by referring to FIGS. 1 and 5 together, and details that are already described with respect to FIG. 8 are briefly described or omitted.

Referring to FIG. 11, in the semiconductor device manufacturing method using multi-wavelengths, according to the present embodiment (hereinafter, simply referred to as ‘semiconductor device manufacturing method’), first, multi-wavelengths for overlay measurement are selected in operation S310. The operation of selecting multi-wavelengths (S310) may be substantially the same as the multi-wavelength selection method of FIG. 1. Therefore, the operation of selecting multi-wavelengths (S210) may include the operation of measuring an overlay (S110), the operation of filtering all the wavelengths (S130), the operation of selecting representative wavelengths (S150), and the operation of allocating weights to the representative wavelengths (S170). The operation of measuring an overlay (S110) to the operation of allocating weights to the representative wavelengths (S170) may be the same as described in the description of FIG. 1.

After selecting multi-wavelengths, an overlay measurement recipe is set up in operation S320. For example, the overlay measurement recipe may include wavelengths used for measurement, weights of the wavelengths, locations to be measured, measurement time, and the like. For example, in the semiconductor device manufacturing method of the present embodiment, setting up an overlay measurement recipe may mainly refer to reflecting previously selected representative wavelengths and weights allocated to the representative wavelengths so that they may be used in overlay measurement.

After setting up the overlay measurement recipe, an overlay is measured based on the newly set-up overlay measurement recipe, in operation S330. In other words, the overlay may be measured based on the selected representative wavelengths and the weights allocated to the representative wavelengths. Here, overlay measurement may refer to overlay measurement for an overlay mark. According to the semiconductor device manufacturing method of the present embodiment, by measuring an overlay through the operation of selecting multi-wavelengths for overlay measurement (S310) and the operation of setting up the overlay measurement recipe (S320), mis-reading components resulting from the asymmetry of an overlay mark may be excluded, and the overlay may be accurately measured.

After measuring the overlay, the overlay is corrected in operation S340. Here, the overlay correction may refer to modifying a process recipe of an exposure process or a patterning process, such that the overlay becomes 0, that is, the patterns of a previous layer and a current layer are aligned. In detail, as an example, overlay correction may refer to a process of modifying a process recipe of an exposure process or a patterning process, such that the pattern may be by −0.5 nm in the y-axis direction to be formed, when an overlay occurs in the y-axis direction by 0.5 nm.

After correcting the overlay, a pattern is formed in operation S350. The pattern may be formed based on the process recipe of the exposure process or the patterning process in which overlay correction is reflected. Thus, the overlay of the pattern may be different from a previous overlay measured before overlay correction, and may also be smaller than the previous overlay. The forming of the pattern may include forming an overlay mark, and the overlay mark may also be formed based on the process recipe of the exposure process or the patterning process in which overlay correction is reflected.

After forming the pattern, it is determined whether the overlay of the pattern is within a set range, in operation S360. The overlay of the pattern may be measured using overlay marks. Also, according to embodiments, the overlay of the pattern may be measured through direct overlay measurement on the pattern.

When the overlay of the pattern is within the set range (YES), a subsequent semiconductor process is performed in operation S370. A subsequent semiconductor process may include various processes. For example, the subsequent semiconductor process may include a deposition process, an etching process, an ion process, a cleaning process, and the like. In addition, the subsequent semiconductor process may include a singulation process of individualizing a wafer into individual semiconductor chips, a test process of testing semiconductor chips, and a packaging process of packaging semiconductor chips. A semiconductor device may be completed through a subsequent semiconductor process on a wafer.

For reference, in the semiconductor device manufacturing method of the present embodiment, a target wafer in overlay measurement in the operation of selecting multi-wavelengths (S310), a target wafer in overlay measurement in the overlay measurement operation (S330), and a target wafer in the operation of forming a pattern (S350) may be different from each other. For example, the target wafers in the operation of selecting multi-wavelengths (S310) and the overlay measurement operation (S330) may correspond to a test wafer. Meanwhile, the target wafer of the operation of the forming a pattern (S350) may be a test wafer or an actual wafer on which an actual pattern is formed.

If the overlay of the pattern is out of a set range (NO), a cause thereof is analyzed in operation S380, and the process proceeds to the operation of selecting multi-wavelengths (S310). Based on the cause found in the operation of analyzing a cause (S380), in the operation of selecting multi-wavelengths (S310), representative wavelengths to be selected and weights allocated to the representative wavelengths may be changed.

That is, according to the semiconductor device manufacturing method of the present embodiment, by selecting representative wavelengths that similarly simulate the overlay of all the plurality of wavelengths and measuring an overlay by using the representative wavelengths and the weight of the representative wavelengths, mis-reading components resulting from the asymmetry of an overlay mark may be excluded, and the overlay, that is, misalignment, may be accurately measured. Therefore, in the semiconductor device manufacturing method of the present embodiment, overlay correction may be performed more accurately, based on overlay measurement accuracy, and the level of on-cell overlay, that is, pattern overlay, may be remarkably improved after overlay correction. As a result, according to the semiconductor device manufacturing method of the present embodiment, a reliable semiconductor device may be implemented.

While the inventive concept has been particularly shown and described with reference to embodiments thereof, it will be understood that various changes in form and details may be made therein without departing from the spirit and scope of the following claims.

1. A multi-wavelength selection method for overlay measurement, the method comprising:
measuring an overlay at multiple positions on a wafer at each of a plurality of wavelengths within a set first wavelength range;
selecting representative wavelengths that simulate the overlay of the plurality of wavelengths from among the plurality of wavelengths; and
allocating weights to the representative wavelengths, respectively.

2. The method of claim 1, wherein the selecting of the representative wavelengths is performed based on principal component analysis (PCA).

3. The method of claim 1, wherein the selecting of the representative wavelengths is performed based on singular value decomposition (SVD).

4. The method of claim 3, wherein the measuring of the overlay comprises:
obtaining an overlay for each of the multiple positions with respect to each of the plurality of wavelengths, and
wherein the selecting of the representative wavelengths comprises:
extracting T eigenvectors corresponding to a total number of the plurality of wavelengths through SVD, where T is an integer greater than 1;
selecting n representative eigenvectors from the T eigenvectors based on weights of the T eigenvectors, where n is greater than or equal to 1 and less than T;
with respect to the representative eigenvectors, selecting and fitting n wavelength combinations of ones of the plurality of wavelengths and calculating fitting scores; and
selecting a wavelength combination of the n wavelength combinations having a smallest fitting score,
wherein ones of the plurality of wavelengths included in the selected wavelength combination correspond to the representative wavelengths.

5. The method of claim 4, wherein n is less than or equal to ten;
wherein the representative eigenvectors are selected in an order of highest weight, and
wherein the fitting scores are calculated by a sum of fitting scores with respect to the representative eigenvectors.

6. (canceled)

7. The method of claim 4, wherein calculating the fitting scores, comprises:
calculating a radial basis function (RBF) fitting score for each combination of a combination _{T}Cn for selecting n from T, and
wherein selecting the wavelength combination, comprises:
selecting a wavelength combination having a smallest RBF fitting score.

8. (canceled)

9. The method of claim 1, wherein allocating the weights to the representative wavelengths, comprises:
allocating weights by selecting a weight combination having a smallest mis-reading correction (MRC) distribution among weight combinations in which a sum of the weights equals 1, and
wherein the MRC is a difference between an overlay of an overlay mark and an on-cell overlay.

10. The method of claim 1, further comprising, before the selecting of the representative wavelengths, filtering all of the plurality of wavelengths,
wherein the selecting of the representative wavelengths comprises selecting the representative wavelengths among all of the filtered wavelengths.

11. The method of claim 10, wherein the filtering is performed using a key parameter index (KPI) in which the characteristics of an overlay mark are reflected.

12. An overlay measurement method comprising:
selecting a plurality of wavelengths for overlay measurement;
setting up an overlay measurement recipe based on the plurality of wavelengths; and
measuring an overlay by using the plurality of wavelengths based on the overlay measurement recipe,
wherein the selecting of the plurality of wavelengths comprises:
measuring an overlay at multiple positions on a wafer at each of the plurality of wavelengths within a set wavelength range;
selecting representative wavelengths that simulate the overlay of the plurality of wavelengths from among the plurality of wavelengths; and
allocating weights to the representative wavelengths, respectively.

13. (canceled)

14. The method of claim 12, wherein the measuring of the overlay comprises:
obtaining an overlay for each of the multiple positions with respect to each of the plurality of wavelengths, and
wherein the selecting of the representative wavelengths comprises:
extracting T eigenvectors corresponding to a total number of the plurality of wavelengths through SVD, where T is an integer greater than 1;
selecting n representative eigenvectors from the T eigenvectors based on weights of the T eigenvectors, where n is greater than or equal to 1 and less than T;
with respect to the representative eigenvectors, selecting and fitting n wavelength combinations of ones of the plurality of wavelengths and calculating fitting scores; and
selecting a wavelength combination of the n wavelength combinations having a smallest fitting score,
wherein ones of the plurality of wavelengths included in the selected wavelength combination correspond to the representative wavelengths.

15. The method of claim 12, wherein allocating the weights to the representative wavelengths, comprises:
allocating weights by selecting a weight combination having a smallest mis-reading correction (MRC) distribution among weight combinations in which a sum of the weights equals 1.

16. The method of claim 12, further comprising, before the selecting of the representative wavelengths, filtering all of the plurality of wavelengths,
wherein the selecting of the representative wavelengths comprises selecting the representative wavelengths among all of the filtered wavelengths, and
wherein the filtering is performed using a key parameter index (KPI) in which the characteristics of an overlay mark are reflected.

17. The method of claim 12, wherein setting up of the overlay measurement recipe, comprises:
setting up the overlay measurement recipe based on the representative wavelengths and the weights of the representative wavelengths.

18. A semiconductor device manufacturing method, the method comprising: selecting a plurality of wavelengths for overlay measurement;
setting up an overlay measurement recipe based on the plurality of wavelengths;
measuring an overlay by using the plurality of wavelengths based on the overlay measurement recipe;
correcting the overlay and forming a pattern based on the measured overlay;
determining whether an overlay of the pattern is within a set reference range; and
when the overlay of the pattern is within the reference range, performing a subsequent semiconductor process.

19. The method of claim 18, wherein, the selecting of the multi-wavelengths comprises:
measuring an overlay at multiple positions on a wafer at each of the plurality of wavelengths within a set wavelength range;
selecting representative wavelengths that simulate the overlay of the plurality of wavelengths from among the plurality of wavelengths; and
allocating weights to the representative wavelengths, respectively.

20. The method of claim 19, wherein the selecting of the representative wavelengths is performed based on singular value decomposition (SVD), and
wherein the measuring of the overlay, comprises:
obtaining an overlay for each of the multiple positions with respect to each of the plurality of wavelengths, and
wherein the selecting of the representative wavelengths comprises:
extracting T eigenvectors corresponding to a total number of the plurality of wavelengths through SVD, where T is an integer greater than 1;
selecting n representative eigenvectors from the T eigenvectors based on weights of the T eigenvectors, where n is greater than or equal to 1 and less than T;
with respect to the representative eigenvectors, selecting and fitting n wavelength combinations of ones of the plurality of wavelengths and calculating fitting scores; and
selecting a wavelength combination of the n wavelength combinations having a smallest fitting score,
wherein ones of the plurality of wavelengths included in the selected wavelength combination correspond to the representative wavelengths.

21. The method of claim 19, wherein allocating the weights to the representative wavelengths, comprises:
allocating weights by selecting a weight combination having a smallest mis-reading correction (MRC) distribution among weight combinations in which a sum of the weights equals 1.

22. The method of claim 19, further comprising, before the selecting of the representative wavelengths, filtering all of the plurality of wavelengths,
wherein the selecting of the representative wavelengths comprises selecting the representative wavelengths among all of the filtered wavelengths, and
wherein the filtering is performed using a key parameter index (KPI) in which the characteristics of an overlay mark are reflected.

23. The method of claim 19, wherein setting up of the overlay measurement recipe, comprises:
setting up the overlay measurement recipe based on the representative wavelengths and the weights of the representative wavelengths.
